(19) United States
(12) Patent Application Publication
(10) Pub. No.: US 2002/0135054 A1
(43) Pub. Date: Sep. 26, 2002

(54) Fixing device and method for the same

(76) Inventor: Shui-Ching Lee, Pingtung Hsien (TW)

Correspondence Address: J.C. Patents, Inc., 4 Venture, Suite 250, Irvine, CA, 92618, US

(21) Appl. No.: 09/853,421

(22) Filed: May 11, 2001

(30) Foreign Application Priority Data
Mar. 21, 2001 (TW) 90106571

(51) Int. Cl. H01L 23/02

(52) U.S. Cl. 257/678

(57) ABSTRACT

A fixing means for fixing a ceramic substrate during wire bonding is provided. The fixing means comprises: a carrier for supporting the ceramic substrate, wherein the carrier has a first opening covered by the ceramic substrate; a socket for supporting the carrier, the socket having a second opening to communicate with the first opening, wherein the second opening and the first opening define a space; a fixing member having at least a vertical vacuum through channel, wherein the fixing member moves along the space to contact with the substrate; and, optionally, a pressing plate to press the carrier under cooperation with the fixing member.

### CROSS-REFERENCE TO RELATED APPLICATION

This application claims the priority benefit of Taiwan application serial no. 90106571, filed on Mar. 21, 2001.

### BACKGROUND OF THE INVENTION

1. Field of the Invention

The present invention relates to a fixing means and a fixing method. More specifically, the present invention relates to a fixing means and a fixing method useful for a ceramic substrate.

2. Description of the Related Art

As semiconductor technology progresses, electronic devices tend to have various functions, smaller dimensions, and greater memory, etc. Many types of packages that meet commercial demands have been developed and put into practice. For commercial availability, a plastic substrate or a ceramic substrate is often used as a substrate for packaging. In an example of a ball grid array package, a ceramic low profile ball grid array package uses a ceramic substrate having a thickness of about 0.45 mm, which is liable to be broken by a conventional fixing means.

FIG. 1 is a schematic, cross sectional view showing a conventional fixing means for fixing a ceramic substrate. A carrier 110 having a first opening 112 is provided to support a ceramic substrate 120. A socket 130 having a surface 132 and a second opening 134 are provided in which the second opening 134 passes through the surface 132 under the first opening 112 of the carrier 110. The cross section of the second opening 134 is larger than that of the first opening 112. A fixing member 140 having a surface 142 is provided in the second opening 134, and the fixing member 140 can move vertically in the second opening 134. The front end of the fixing member 140 fits into the first opening 112 of the carrier 110 to press against the ceramic substrate 120 which is located at the top of the first opening 112. A circular plate 150 is provided above the surface 132. Then, the carrier 110 is placed on the planar surface 132 such that the first opening 112 of the carrier 110 communicates with the second opening 134. The fixing member 140 moves to the first opening 112 and the surface 142 presses against the ceramic substrate 120. The circular plate 150 is pressed against the circumference of the ceramic substrate 120 to fix the substrate 120. When the ceramic substrate 120 is fixed, other processes such as wire bonding can be carried out on the top of the ceramic substrate.

If the carrier 110 is bent during the fixing process, the ceramic substrate 120 can not be attached effectively on the carrier 110, resulting in insufficient support of the ceramic substrate 120. Therefore, it is difficult for the fixing member 140 and the circular plate 150 to fix the ceramic substrate 120. When the fixing member 140 and the circular plate 150 are pressed against the ceramic substrate 120, the ceramic substrate 120 can be broken. During wire bonding, the ceramic substrate 120 can not be attached effectively to the carrier, causing the bond that is formed thereon later to have a shorter service life. Further, the wire bonding is carried out with low precision.

### SUMMARY OF THE INVENTION

It is one object of the present invention to provide a fixing means and a fixing method for preventing a substrate from being suspended and for fixing the substrate without breakage.

It is another object of the present invention to provide a fixing means and a fixing method in which a bonding head suffers a more uniform force during wire bonding, thereby increasing the service life of the bonding head and the precision of wire bonding.

In order to achieve the above and other objects of the present invention, a fixing means for fixing a ceramic substrate during wire bonding is provided. The fixing means comprises a carrier for supporting the ceramic substrate and a socket for supporting the carrier. The carrier has a first opening covered by the ceramic substrate. The socket has a second opening to communicate with the first opening. The second opening and the first opening define a space. The socket is further provided with a fixing member capable of moving in the space. The fixing member has at least a vertical vacuum channel. The fixing member moves along the space to contact with substrate, when the carrier supports the substrate..

In one aspect of the present invention, the carrier is formed of stacked stencils. The carrier is formed by laser ablating, etching or welding.

Furthermore, a method for fixing a ceramic substrate during wire bonding is also provided. In the method of the present invention, a carrier is used to support the ceramic substrate. The carrier has a first opening covered by the ceramic substrate. A socket having a second opening to communicate with the first opening is provided for supporting the carrier. A fixing member having a surface and at least a channel penetrating the surface is provided. A pressing plate can be optionally provided. The carrier is placed on the surface to communicate the first opening with the second opening. The second opening and the first opening define a space where the fixing member can move. The pressing plate presses against the carrier, and the fixing member comes into contact with the bottom of the substrate such that the substrate is fixed by suction through the channel.

### BRIEF DESCRIPTION OF THE DRAWINGS

It is to be understood that both the foregoing general description and the following detailed description are exemplary, and are intended to provide further explanation of the invention as claimed.

The accompanying drawings are included to provide a further understanding of the invention, and are incorporated in and constitute a part of this specification. The drawings illustrate embodiments of the invention and, together with the description, serve to explain the principle of the invention. In the drawings,

FIG. 1 is a schematic, cross sectional view showing a conventional fixing means for fixing a ceramic substrate;

FIG. 2 is a schematic, cross sectional view showing a fixing means for fixing a ceramic substrate according to one preferred embodiment of the present invention.

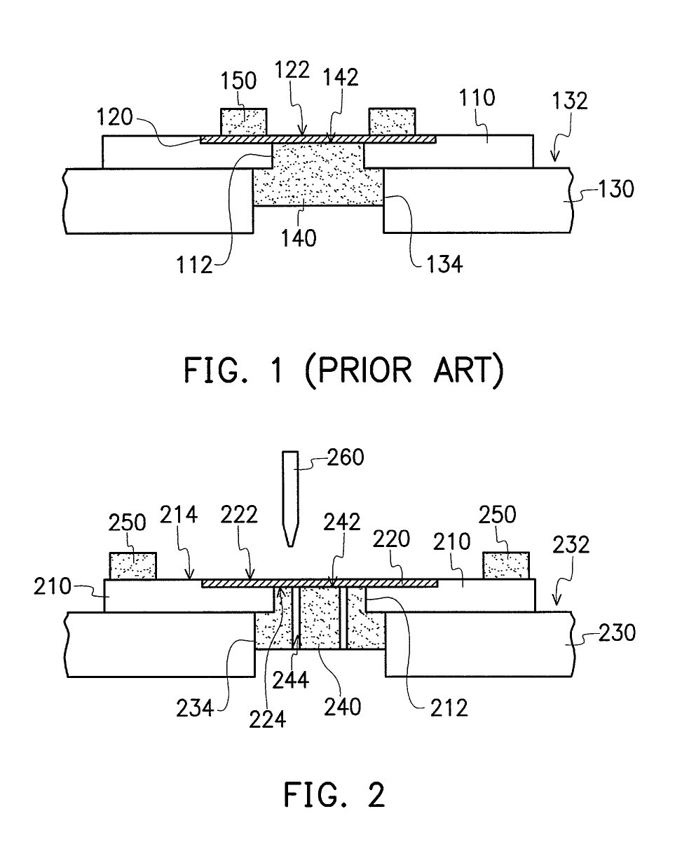

### DESCIPTION OF THE PREFERRED EMBODIMENT

Reference will now be made in detail to the present preferred embodiments of the invention, examples of which are illustrated in the accompanying drawings. Whenever possible, the same reference numbers are used in the drawings and the description to refer to the same or like parts.

FIG. 2 is a schematic, cross sectional view showing a fixing means for fixing a ceramic substrate according to one preferred embodiment of the present invention.

With reference to FIG. 2, the fixing means of the present invention can comprise a carrier 210, a socket 230, a fixing member 240, and a pressing plate 250. The carrier 210 is used to support a ceramic substrate 220. The carrier 210 has a first opening 212 on which the ceramic substrate 220 is applied. The carrier 210 can be formed of stacked stencils, for example by laser ablating, etching or welding.

The socket 230 is used to support the carrier 210. The socket is further provided with a surface 232 and a second opening 234 passing through the surface 232.

The fixing member 240 has a surface 242 and a plurality of channels 244 penetrating the surface 242.

The pressing plate 250 can be a circular shape and is located on the surface 232.

The carrier 210 is put on the surface 232 by a fixture (not shown) to communicate the first opening 212 with the second opening 234. The second opening 234 has a cross section larger than the first opening 212. Preferably, the middle region of the first opening 212 is substantially aligned with that of the second opening 234. The second opening 234 and the first opening 212 define a space where the fixing member 240 can move vertically. The front end of the fixing member 240 must fit into the first opening 212 of the carrier 210.

The pressing plate 250 presses against the carrier 210, while moving the fixing member 240 in the first opening 212 in order to press against the ceramic substrate 220 by the surface 242. The ceramic substrate 220 is fixed by suction through the channel 244.

After the ceramic substrate 220 is fixed, other processes can be carried out on the top surface 222 of the ceramic substrate 220. In the case that wire bonding is achieved by using a wire bonder, the fixing member 240 has to be heated to provide the bonding region with a sufficient temperature, and a bonding head 260 is used to form a bond. The bonding head 260 is above the second opening 234. The bonding head 260 can be driven by a driving mechanism (not shown). When wire bonding is performed, the channel 244 is vented and the fixing member 240 moves from the first opening 212 to stand outside of the ceramic substrate 220. Meanwhile, the pressing plate 250 also moves from the carrier 210. A fixture (not shown) moves the carrier 210 from the socket 230.

During wire bonding, the fixing member 240 comes into contact with the bottom surface 224 of the ceramic substrate 220. The pressing plate 250 presses against the surface 214 of the carrier 210 to fix the carrier 210. In this way, the pressing plate 250 allows the carrier to have a planar surface. The fixing member 240 provides support to the ceramic substrate 220 from the bottom thereof, such that the ceramic substrate 220 is not suspended. Therefore, the ceramic substrate does not break, thereby increasing the yield of the product. Furthermore, during wire bonding, the bonding head 260 suffers a more uniform force. An extended service life of the bonding head and an increased wire-bonding precision can be thus obtained.

From a view of foregoing, the present invention can provide the following advantages:

1. By using the pressing plate that can make the carrier more planar and the fixing member that supports the ceramic substrate, the ceramic substrate 220 is not suspended. Additionally, the ceramic substrate is fixed easily and is not easily broken, thereby increasing the yield of the product.

2. Since the pressing plate presses the carrier, instead of the top surface of the ceramic substrate, breakage does not occur on the top surface of the ceramic substrate.

3. According to the present invention, the substrate is not suspended. During wire bonding, the bonding head suffers more uniform force, thereby increasing the service life of the bonding head and the precision of the wire bonding.

It will be apparent to those skilled in the art that various modifications and variations can be made to the structure of the present invention without departing from the scope or spirit of the invention. In view of the forgoing, it is intended that the present invention cover modifications and variations of this invention provided they fall within the scope of the following claims and their equivalents.

What is claimed is:

1. A fixing means for fixing a ceramic substrate during wire bonding, comprising:
a carrier for supporting the ceramic substrate, wherein the carrier has a first opening covered by the ceramic substrate;
a socket for supporting the carrier, the socket having a second opening to communicate with the first opening, wherein the second opening and the first opening define a space;
a fixing member having at least a vertical vacuum channel, wherein the fixing member moves along the space to contact with the substrate; and
a pressing plate to press the carrier to the fixing member.

2. The fixing means of claim 1, wherein the center of the first opening is substantially aligned with that of the second opening.

3. The fixing means of claim 1, wherein the carrier is composed of stacked stencils.

4. The fixing means of claim 1, wherein the carrier is formed by laser ablating, etching or welding.

5. A fixing means for fixing a ceramic substrate during wire bonding, the fixing means comprising:
a carrier for supporting the ceramic substrate, wherein the carrier has a first opening covered by the ceramic substrate;
a socket for supporting the carrier, the socket having a second opening to communicate with the first opening, wherein the second opening and the first opening define a space; and
a fixing member having at least a vertical vacuum through channel, wherein the fixing member moves along the space to contact with the substrate.

6. The fixing means of claim 5, wherein the center of the first opening is substantially aligned with that of the second opening.

7. The fixing means of claim 5, wherein the carrier is formed of stacked stencils.

8. The fixing means of claim 5, wherein the carrier is formed by laser ablating, etching or welding.

9. A method for fixing a ceramic substrate during wire bonding, comprising:
proving a carrier for supporting the ceramic substrate, wherein the carrier has a first opening covered by the ceramic substrate;
providing a socket for supporting the carrier, the socket having a second opening to communicate with the first opening;
providing a fixing member having at least a vertical vacuum through channel;
providing a pressing plate to press the carrier to the fixing member;
placing the carrier on the surface to communicate the first opening with the second opening, wherein the second opening and the first opening define a space where the fixing member can move; and
fixing the substrate, wherein the pressing plate presses against the carrier and the fixing member comes into contact with the bottom of the substrate such that the substrate is fixed by vacuum suction.

10. The method of claim 9, wherein the center of the first opening is substantially aligned with that of the second opening.

11. The method of claim 9, wherein the carrier is formed of stacked stencils.

12. The method of claim 9, wherein the carrier is formed by laser ablating, etching or welding.

13. A method for fixing a ceramic substrate during wire bonding, comprising:
proving a carrier for supporting the ceramic substrate, wherein the carrier has a first opening covered by the ceramic substrate;
providing a socket for supporting the carrier, the socket having a second opening to communicate with the first opening;
providing a fixing member having at least a vertical vacuum through channel;
placing the carrier on the surface to communicate the first opening with the second opening, wherein the second opening and the first opening define a space where the fixing member can move; and
fixing the substrate, wherein the pressing plate presses against the carrier and the fixing member comes into contact with the bottom of the substrate such that the substrate is fixed by vacuum suction.

14. The method of claim 13, wherein the center of the first opening is substantially aligned with that of the second opening.

15. The method of claim 13, wherein the carrier is formed of stacked stencils.

16. The method of claim 13, wherein the carrier is formed by laser ablating, etching or welding.
